(19) United States
(12) Patent Application Publication
(10) Pub. No.: US 2008/0176364 A1
(43) Pub. Date: Jul. 24, 2008

(54) METHOD OF MANUFACTURING THIN FILM TRANSISTOR SUBSTRATE

(75) Inventors: Sung-Hoon YANG, Seoul (KR); Byoung-June KIM, Seoul (KR); Yong-Mo CHOI, Suwon-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/841,336

(22) Filed: Aug. 20, 2007

(30) Foreign Application Priority Data
Jan. 18, 2007 (KR) 10-2007-0005710

(51) Int. Cl. H01L 29/786

(52) U.S. Cl. 438/151; 257/E29.273

(57) ABSTRACT

The present invention provides a method for manufacturing a thin film transistor substrate including forming gate wires on an insulation substrate, forming oxide active layer patterns on the gate wires, forming data wires on the oxide active layer patterns so that the data wires cross the gate wires, forming a passivation film on the oxide active layer patterns and the data wires using a non-reductive reaction gas and SiH₄, and forming pixel electrodes on the passivation film

### CROSS REFERENCE TO RELATED APPLICATION

This application claims priority from and the benefit of Korean Patent Application No. 10-2007-0005710, filed on Jan. 18, 2007, which is hereby incorporated by reference for all purposes as if fully set forth herein.

### BACKGROUND OF THE INVENTION

1. Field of the Invention

The present invention relates to a method of manufacturing a thin film transistor substrate, and more particularly, to a method of manufacturing a thin film transistor substrate in which the characteristics of oxide active layer patterns may be improved.

2. Discussion of the Background

Presently, a liquid crystal display (LCD) is one of the most widely used flat panel displays. A liquid crystal display is provided with two substrates on which electrodes are formed, and a liquid crystal layer is interposed between the substrates. In the liquid crystal display, voltages are applied to the electrodes to change the orientation of the liquid crystal molecules of the liquid crystal layer, thereby controlling the quantity of transmitted light.

A liquid crystal display generally includes two substrates, which each include a field generating electrode. In the liquid crystal display, a plurality of pixel electrodes is arranged on one substrate (the thin film transistor substrate) in a matrix, and a common electrode is formed on the other substrate (the common electrode substrate) to cover the display area of the substrate. Voltages are applied separately to the pixel electrodes to display images in the liquid crystal display. Thin film transistors may be used as three-terminal elements to switch voltages applied to the pixel electrodes. Further, a plurality of wires is formed on the substrates. The wires include gate lines through which signals used to control the thin film transistors are transmitted and data lines through which voltages to be applied to the pixel electrodes are transmitted.

As the demand for liquid crystal displays has increased and higher quality has been required, there have also been demands for a way to reduce manufacturing costs and improve the quality of liquid crystal displays. A method in which inexpensive glass, for example, soda lime glass, is used as the insulation substrate of the thin film transistor substrate included in the liquid crystal display has been studied in an attempt to meet the demand to reduce manufacturing costs. However, a method of manufacturing a thin film transistor substrate includes a plurality of processes performed at high temperatures, and an insulation substrate including soda lime glass has a large thermal expansion coefficient. For this reason, defects may occur in the thin film transistor substrate during the formation of wires and thin films. Another method, in which an active layer made of a material that can be formed at low temperature and has excellent electric characteristics, for example, metal oxide, has been studied in an attempt to prevent defects from occurring in the thin film transistor substrate. By using an active layer including metal oxide it may be possible to prevent deterioration of the active layer during the forming of a passivation film, thereby preventing a haze from occurring in the thin film transistor substrate.

### SUMMARY OF THE INVENTION

The present invention provides a method of manufacturing a thin film transistor substrate in which the characteristics of oxide active layer patterns is improved.

Additional features of the invention will be set forth in the description which follows, and in part will be apparent from the description, or may be learned by practice of the invention.

The present invention discloses a method of manufacturing a thin film transistor substrate including forming gate wires on an insulation substrate, forming oxide active layer patterns on the gate wires, forming data wires on the oxide active layer patterns so that the data wires cross the gate wires, forming a passivation film on the oxide active layer patterns and the data wires using non-reductive reaction gas and SiH₄, and forming a pixel electrode on the passivation film.

The present invention also discloses a method of manufacturing a thin film transistor substrate including forming gate wires on an insulation substrate, forming oxide active layer patterns on the gate wires, forming data wires on the oxide active layer patterns so that the data wires cross the gate wires, forming a passivation film by depositing a thin film made of SiNₓ on a thin film made of SiOx after depositing a thin film made of SiOx on the oxide active layer patterns and the data wires using nitrous oxide (N₂O) gas and SiH₄, and forming a pixel electrode on the passivation film.

The present invention also discloses a method of manufacturing a thin film transistor substrate including forming gate wires on an insulation substrate, forming oxide active layer patterns on the gate wires, forming data wires on the oxide active layer patterns so that the data wires cross the gate wires, exposing the oxide active layer patterns to plasma using non-reductive reaction gas, forming a passivation film on the oxide active layer patterns and the data wires, and forming a pixel electrode on the passivation film.

The present invention also discloses a method of manufacturing a thin film transistor substrate including forming gate wires on an insulation substrate, forming oxide active layer patterns on the gate wires, forming data wires on the oxide active layer patterns so that the data wires cross the gate wires, forming a passivation film on the oxide active layer patterns and the data wires, and forming a pixel electrode on the passivation film. In this case, the forming of the passivation film is performed by chemical vapor deposition at a temperature of 200° C. or less.

It is to be understood that both the foregoing general description and the following detailed description are exemplary and explanatory and are intended to provide a further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1, FIG. 2, FIG. 3, FIG. 4, FIG. 5, FIG. 6, FIG. 7, FIG. 8, FIG. 9, FIG. 10, and FIG. 11 are cross-sectional views showing a method of manufacturing a thin film transistor substrate according to a first exemplary embodiment of the present invention.

FIG. 12 and FIG. 13 are graphs showing the characteristics of the oxide active layer pattern during the formation of the passivation film in the method of manufacturing a thin film transistor substrate according to the first exemplary embodiment of the present invention.

FIG. 14, FIG. 15, FIG. 16, FIG. 17, FIG. 18, and FIG. 19 are cross-sectional views showing a method of manufacturing a thin film transistor substrate according to a second exemplary embodiment of the present invention.

FIG. 20, FIG. 21, FIG. 22, FIG. 23, FIG. 24, and FIG. 25 are cross-sectional views showing a method of manufacturing a thin film transistor substrate according to a third exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or a layer is referred to as being “on” or “connected to” another element or layer, it can be directly on or directly connected to the other element, or intervening elements may also be present. In contrast, when an element is referred to as being “directly on” or “directly connected to” another element, there are no intervening elements present.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

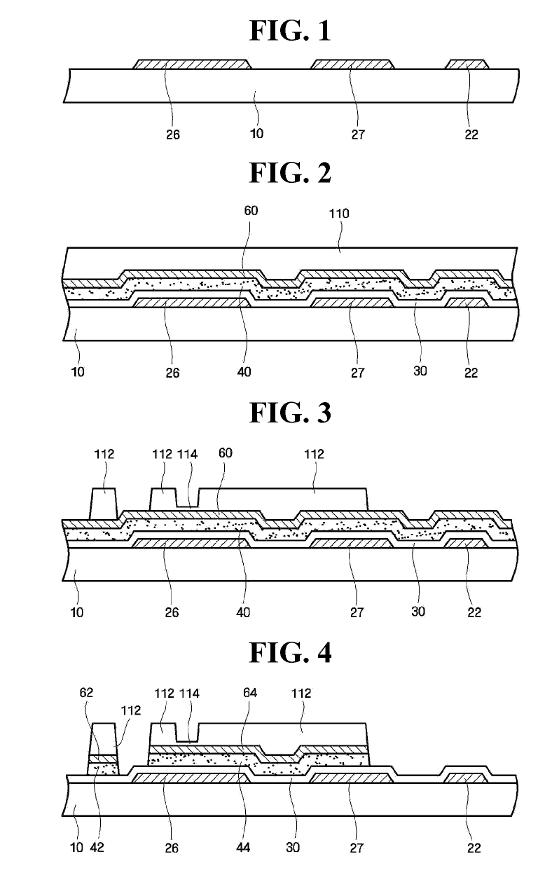

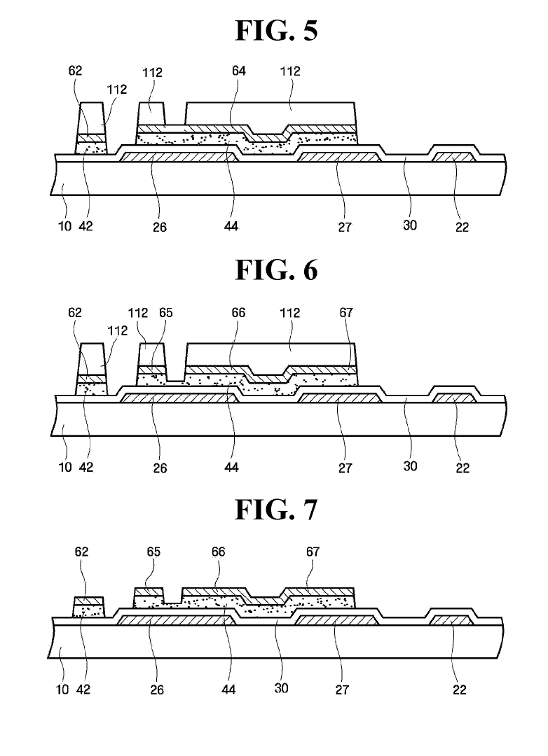

Hereinafter, a method of manufacturing of a thin film transistor substrate according to a first exemplary embodiment of the present invention will be described in detail with reference to FIG. 1, FIG. 2, FIG. 3, FIG. 4, FIG. 5, FIG. 6, FIG. 7, FIG. 8, FIG. 9, FIG. 10, and FIG. 11, which are cross-sectional views showing a method of manufacturing a thin film transistor substrate according to a first exemplary embodiment of the present invention.

First, as shown in FIG. 1, a gate wire metal film (not shown) is laminated on an insulation substrate 10 and then patterned to form gate wires 22, 26, and 27, which are composed of a gate line 22, a gate electrode 26, and a storage electrode 27.

The insulation substrate 10 of this exemplary embodiment may be made of, for example, soda lime glass. The manufacturing cost of soda lime glass is less than that of boro-silicate glass, such as alkali-free glass or alumino-boro-silicate glass. However, since alkali metal oxides, such as Na₂O or K₂O, are contained in the soda lime glass, the network structures of the glass are cut, so the amount of unbridged oxygen may be increased. For this reason, the melting point of the glass may be lowered, and the expansion and shrinkage percentages vary with changes in temperature. Specifically, the thermal expansion coefficient of soda lime glass is about 2.7 times as high as that of boro-silicate glass. When soda lime glass is used as the insulation substrate 10 to reduce the manufacturing cost of the thin film transistor substrate, the insulation substrate 10 may be bent or broken or misalignment may occur in the following thermal treatment process. For this reason, the following processes may be performed at low temperatures to prevent deterioration of the insulation substrate 10.

In this case, a sputtering method may be used to form the gate wires, which are composed of a gate line 22, a gate electrode 26, and a storage electrode 27. That is, first, a conductive film made of aluminum-based metal such as aluminum (Al) or an aluminum alloy, a conductive film made of silver-based metal such as silver (Ag) or a silver alloy, a conductive film made of copper-based metal such as copper (Cu) or a copper alloy, a conductive film made of molybdenum-based metal such as molybdenum (Mo) or a molybdenum alloy, and a conductive film made of chromium (Cr), titanium (Ti), or tantalum (Ta) are deposited using, for example, a sputtering method or the like. Sputtering may be performed at a temperature of 200° C. or less. Since the gate wire metal film may be formed using the above-mentioned low-temperature sputtering method, it may be possible to prevent deterioration of the insulation substrate 10 made of soda lime glass. Subsequently, wet etching or dry etching may be performed on these conductive films to pattern the conductive films. Etchant such as phosphoric acid, nitric acid, or acetic acid may be used in the wet etching.

The gate line 22 is formed on the insulation substrate 10, for example, in a transverse direction. The gate electrode 26 is connected to and protrudes from the gate line 22.

Further, a storage electrode line (not shown), which crosses pixel regions and extends in the transverse direction substantially parallel to the gate line 22, is formed on the insulation substrate 10. In addition, the storage electrode 27, which is connected to the storage electrode line and has a large width, is formed on the insulation substrate 10. The storage electrode 27 overlaps a drain electrode expanding portion 67, which is connected to a pixel electrode 82 to be described below, to form a storage capacitor, which may improve the electric charge storage ability of pixels.

The shapes and arrangements of the storage electrode 27 and the storage electrode line may be modified in various ways. If storage capacitance caused by the 27 overlap of the pixel electrode 82 and the gate line 22 is sufficient, the storage electrode and the storage electrode line may be omitted.

Subsequently, as shown in FIG. 2, a gate insulating film 30, which may be made of silicon nitride (SiNₓ), is deposited on the insulation substrate 10 and the gate wires 22, 26, and 27 by, for example, a plasma enhanced chemical vapor deposition method (PECVD) or reactive sputtering method. The gate insulating film 30 may be formed at a temperature of 100° C. or less to prevent deterioration of the insulation substrate 10.

Further, an oxide active layer 40 and a data wire conductive film 60 are sequentially deposited on the gate insulating film 30 by, for example, a sputtering method. If the oxide active layer 40 and the data wire conductive film 60 are sequentially deposited on the gate insulating film 30 under a vacuum, it may be possible to prevent deterioration of the oxide active layer 40, which is caused by oxygen. Further, a sputtering method, which can perform deposition at a temperature of 100° C. or less, may be used to form the oxide active layer 40 and the data wire conductive film 60. As a result, it may be possible to prevent deterioration of the insulation substrate 10, which may be made of soda lime glass. The oxide active layer 40 may be made of an active material. In this case, “active” means that the material forming the oxide active layer 40, which may include semiconductors and metal oxides, has electrical characteristics when a driving current is applied.

The oxide active layer 40 may be made of oxides of materials such as Zn, In, Ga, Sn, and combinations thereof. For example, the oxide active layer 40 may be made of a mixed oxide such as ZnO, InZnO, InGaO, InSnO, ZnSnO, GaSnO, GaZnO, or GaInZnO. It is preferable that the oxide active layer 40 be made of ZnO, InZnO, or GaInZnO. The oxide active layer 40 has excellent semiconductor characteristics including an effective mobility of electric charges that is about five to six times as high as hydrogenated amorphous silicon and excellent stability. Further, since the materials forming the oxide active layer 40 have excellent ohmic contact characteristics against the data wires (see 62, 65, 66, and 67 in FIG. 6), a separately formed ohmic contact layer may not be needed. As a result, it may be possible to reduce processing time.

In addition, the data wire conductive film 60 may be made of a material, which comes into direct contact with the oxide active layer 40 to form an ohmic contact. That is, the data wire conductive film 60 may be made of a material, which has a work function smaller than that of the oxide active layer 40. For example, the data wire conductive film 60 may have a single layer or multilayer structure, which may be formed of Ni, Co, Ti, Ag, Cu, Mo, Al, Be, Nb, Au, Fe, Se, or Ta. The multilayer structure may include a dual layer, such as Ta/Al, Ta/Al, Ni/Al, Co/Al, or Mo (Mo alloy)/Cu, or a triple-layer, such as Ti/Al/Ti, Ta/Al/Ta, Ti/Al/TiN, Ta/Al/TaN, Ni/Al/Ni, Co/Al/Co, Mo/Al/Mo, or Cr/Al/Cr.

Subsequently, a photoresist film 110 is applied on the data wire conductive film 60.

Then, referring to FIG. 2 and FIG. 3, after light is radiated onto the photoresist film 110 through a mask, the photoresist film 110 is developed to form photoresist film patterns 112 and 114. In this case, a channel portion of the thin film transistor of the photoresist film patterns 112 and 114, that is, the photoresist film pattern 114 between the a source electrode (see 65 in FIG. 6) and a drain electrode (see 66 in FIG. 6), has a thickness that is smaller than a data wire portion, that is, the photoresist film pattern 112 position at a position at which a data wire is formed. Further, all of the photoresist film is removed except for the channel portion and data wire portion. In this case, the ratio of the thickness of the photoresist film pattern 114 remaining on the channel portion to the thickness of the photoresist film pattern 112 remaining on the data wire portion may depend on the processing conditions of an etching process to be described below.

As described above, various methods may be used to change the thickness of the photoresist film, which may be made of a reflowable material. Further, a mask, which generally uses slits, lattice patterns, or a translucent film, may be used to control the amount of transmitted light. In addition, exposure may be performed using a general mask. That general mask may be divided into portions through which light is completely transmitted and portions through which light is not transmitted. Then, development and reflow may be performed so that the photoresist film partially flows into portions in which the photoresist film was removed. As a result, it may possible to form a thin photoresist film pattern 114.

Subsequently, referring to FIG. 3 and FIG. 4, the photoresist film patterns 112 and 114 are used as an etch mask to etch the data wire conductive film 60. Wet etching or dry etching may be used to etch the data wire conductive film. Etchant such as a mixture of phosphoric acid, nitric acid, and acetic acid, or a mixture of hydrofluoric acid (HF) and deionized water may be used to perform wet etching. Accordingly, only the data line 62 and the source/drain conductive film pattern 64 remain, and all of the data wire conductive film 60 is removed except in the areas corresponding to the data line and the source/drain conductive film pattern. As a result, the oxide active layer 40 formed below the data wire conductive film may be exposed. In this case, the shapes of the residual data line 62 and the source/drain conductive film pattern 64 are the same as the shapes of the data wires (62, 65, 66, and 67 in FIG. 6) except that the source electrode (see 65 in FIG. 6) and the drain electrode (see 66 in FIG. 6) are not spaced apart from each other and are connected to each other.

Subsequently, while the photoresist film patterns 112 and 114 are used as etch masks, the oxide active layer 40 is etched to form oxide active layer patterns 42 and 44. In this case, the oxide active layer 40 alone may be etched and the gate insulating film 30 may not be etched. Wet etching or dry etching may be used to etch the oxide active layer 40. Etchant, in which deionized water is mixed with hydrofluoric acid (HF), sulphuric acid, hydrochloric acid, or a combination thereof, may be used to perform wet etching. Fluorine-based etching gas, for example, CHF₃, CF₄, or the like may be used to perform dry etching. Specifically, an etching gas in which Ar or He is contained in fluorine-based etching gas may be used to perform dry etching.

Further, it may be possible to pattern the data wire conductive film 60 and oxide active layer 40 shown in FIG. 3 and FIG. 4 simultaneously by wet etching. For example, if the data wire conductive film 60 is made of metal such as Al, Mo, or the like and the oxide active layer 40 is made of InZnO or GaInZnO, it may be possible to etch the data wire conductive film 60 and the oxide active layer 40 simultaneously using etchant such as phosphoric acid, nitric acid, acetic acid, or the like. Alternatively, if the data wire conductive film 60 is made of Ti or Ta and the oxide active layer 40 is made of InZnO or GaInZnO, it may possible to etch the data wire conductive film 60 and the oxide active layer 40 simultaneously using etchant including hydrofluoric acid and deionized water.

Subsequently, referring to FIG. 4 and FIG. 5, etch-back may be performed on the photoresist film patterns 112 and 114 to remove the photoresist film pattern 114 corresponding to the channel portion. Then, the residue of the photoresist film remaining on the surface of the source/drain conductive film pattern 64 corresponding to the channel portion may be removed by ashing.

After that, referring to FIG. 5 and FIG. 6, the photoresist film pattern 112 may be used as an etch mask to perform wet etching or dry etching on the source/drain conductive film pattern 64 corresponding to the channel portion. An etchant such as a mixture of phosphoric acid, nitric acid, and acetic acid, or a mixture of hydrofluoric acid (HF) and deionized water may be used to perform wet etching. Further, it may be possible to remove a predetermined thickness of the oxide active layer pattern 44 corresponding to the channel portion.

In this case, the source electrode 65 and the drain electrode 66 may be spaced apart from each other and the data wires 62, 65, 66, and 67 may be completely formed. The data wires 62, 65, 66, and 67 are composed of a data line 62 formed in a longitudinal direction and crossing the gate line 22 to define pixels, a source electrode 65 branched from the data line 62 and extending to the upper portion of the oxide active layer pattern 44, a drain electrode 66 spaced apart from the source electrode 65 and formed on the oxide active layer pattern 44 to face the source electrode 65 with the gate electrode 26 or the channel portion of the thin film transistor interposed therebetween, and a drain electrode expanding portion 67 extending from the drain electrode 66 and having a large area overlapping the storage electrode 27.

Subsequently, referring to FIG. 6 and FIG. 7, the photoresist film pattern 112 remaining on the data wires 62, 65, 66, and 67 is removed.

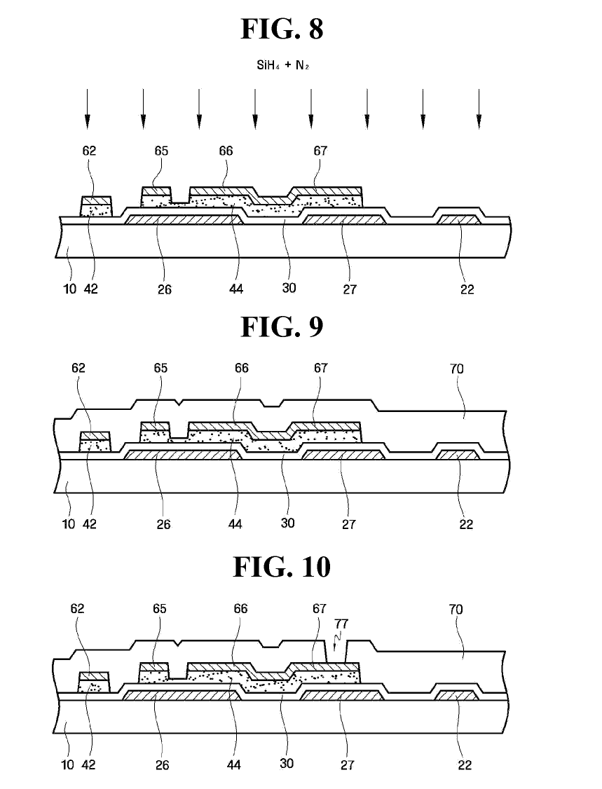

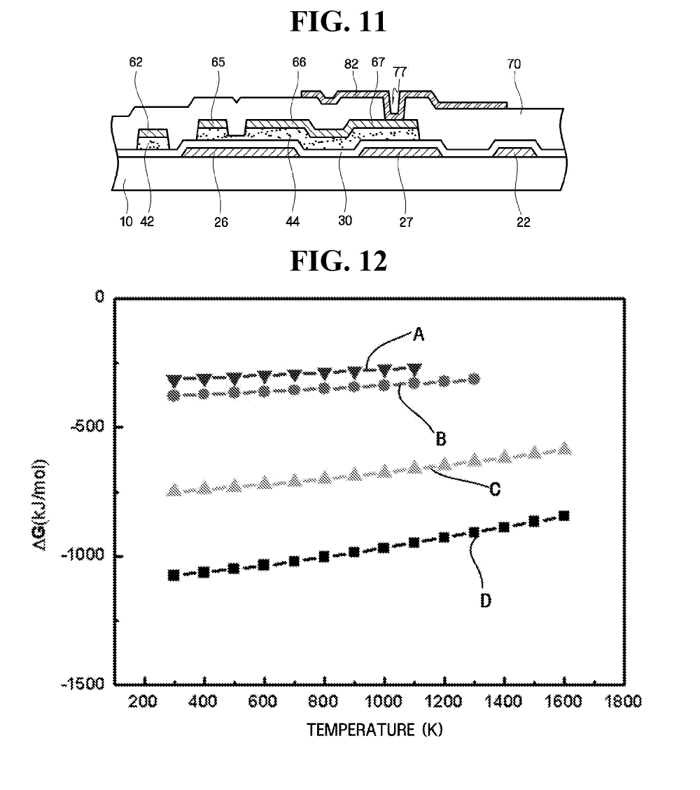

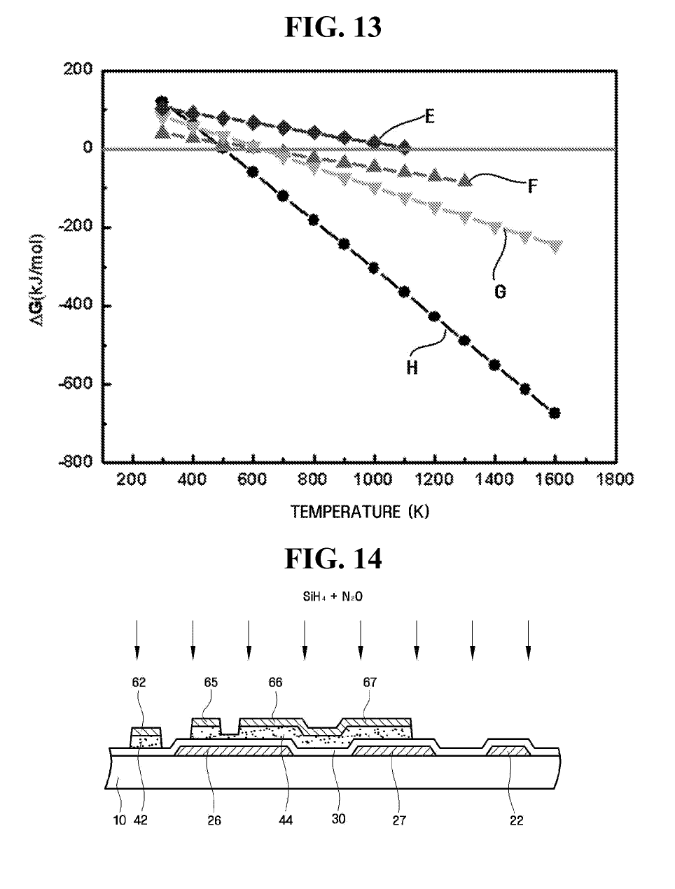

Hereinafter, a process of forming a passivation film 70 of this exemplary embodiment will be described in detail with reference to FIG. 8, FIG. 9, FIG. 12, and FIG. 13. FIG. 12 and FIG. 13 are graphs showing the characteristics of the oxide active layer pattern during the formation of the passivation film in the method of manufacturing a thin film transistor substrate according to the first exemplary embodiment of the present invention.

Referring to FIG. 8 and FIG. 9, the oxide active layer patterns 42 and 44 may be formed on the resultant product using non-reductive reaction gas and SiH₄, and the passivation film 70 may be formed on the data wires 62, 65, 66, and 67. The passivation film 70 may be made by, for example, a reductive chemical vapor deposition method or reductive sputtering method. For example, the passivation film may be made by a low temperature reactive chemical vapor deposition method or a low temperature reactive sputtering method.

When a reductive reaction gas, for example, ammonia gas (NH₃) is used as reaction gas, the oxide forming the oxide active layer patterns 42 and 44 may be reduced. Accordingly, a haze may occur on the thin film transistor substrate. For this reason, a reaction gas that does not include a reductive reaction gas, may be used to form the passivation film 70.

Referring to FIG. 8, FIG. 12, and FIG. 13, when ammonia, which is a reductive reaction gas, is used to form the passivation film 70, ammonia or H radicals decomposed from the ammonia may reduce the oxide active layer patterns 42 and 44. Referring to FIG. 8 and FIG. 12, the variation ΔG of Gibbs free energy before and after the reduction reaction has a negative value regardless of the deposition temperature and the materials deposited in the reduction reaction of the oxide active layer patterns 42 and 44 due to the H radicals. Specifically, “A” denotes a reduction reaction, which is performed by H radicals in accordance with the reaction equation “ZnO+2H=Zn+H₂O”, and “B” denotes a reduction reaction, which is performed by H radicals in accordance with the reaction equation “SnO+2H=Sn+H₂O”. Further, “C” denotes a reduction reaction, which is performed by H radicals in accordance with the reaction equation “SnO₂+4H=Sn+2H₂O”, and “D” denotes a reduction reaction, which is performed by H radicals in accordance with the reaction equation “In₂O₃+6H=2In+3H₂O”. That is, in light of the fact that the variation in Gibbs free energy has a negative value in a deposition reaction of the transparent conductive oxide, such as “A”, “B”, “C”, and “D”, when H radicals exists in the deposition process, it may be possible to deduce that haze occurs on the thin film transistor substrate due to the reduction reaction of the oxide active layer patterns 42 and 44, regardless of the deposition temperature. For this reason, it is desirable to minimize the number of H radicals that may be generated in the deposition process.

Further, referring to FIG. 8 and FIG. 13, the variation of Gibbs free energy has a negative value at high deposition temperatures during the reduction reaction of the oxide active layer patterns 42 and 44 caused by the ammonia gas. However, the variation of Gibbs free energy has a positive value at relatively low deposition temperatures, for example, at 500° C. or less. Specifically, “E” denotes a reduction reaction, which is performed by NH₃ in accordance with the reaction equation “ZnO+⅔NH₃=Zn+H₂O+⅓N₂”, and “F” denotes a reduction reaction, which is performed by NH₃ in accordance with the reaction equation “SnO+⅔NH₃=Sn+H₂O+⅓N₂”. In this case, it is possible to confirm as follows: Since the variation of Gibbs free energy has a negative value at temperatures exceeding about 500° C. in the case of “F”, the reduction reaction may easily occur. However, since the variation of Gibbs free energy has a positive value at temperatures of about 500° C. or less, the reduction reaction may not easily occur. “G” denotes a reduction reaction, which is performed by NH₃ in accordance with the reaction equation “SnO₂+ 4/3NH₃=Sn+2H₂O+⅔N₂”, and “H” denotes a reduction reaction, which is performed by NH₃ in accordance with the reaction equation “In₂O₃+2NH₃=2In+3H₂O+N₂”. In this case, it is possible to confirm as follows: Since the variation of Gibbs free energy has a negative value at temperatures exceeding about 500° C. in the cases of “G” and “H”, the reduction reaction may easily occur. However, since the variation of Gibbs free energy has a positive value at temperatures of about 500° C. or less, the reduction reaction may not easily occur.

Referring to the results of the above-mentioned “E”, “F”, “G” and “H”, it is understood that the reduction reaction of the oxide active layer patterns 42 and 44 caused by ammonia gas may not easily occur at a low deposition temperatures. Accordingly, to prevent the reduction of the oxide active layer patterns 42 and 44, the deposition process may be performed at low temperature, for example, at a temperature of about 500° C. or less, preferably 200° C. or less, and more preferably 150° C. or less.

Among the reductive chemical vapor deposition methods of this exemplary embodiment, the deposition method performed at a low temperature, the deposition method performed using non-reductive reaction gas, or a combination thereof may be used.

Returning to FIG. 8, gas that does not include hydrogen elements may be used as the non-reductive reaction gas in this exemplary embodiment. For example, nitrogen gas (N₂) may be used as the non-reductive reaction gas. According to this process, reductive chemical vapor deposition may be performed using SiH₄, and nitrogen gas may be used as the non-reductive reaction gas. In this case, the flux ratio of SiH₄ to non-reductive reaction gas may be set to 1:10 to 1:100 in consideration of the deposition rate and the material of the film formed by the deposition.

The reductive chemical vapor deposition may be performed as described above, to form the passivation film 70 shown in FIG. 9. When SiH₄ and a non-reductive reaction gas such as nitrogen gas, are used as the reaction gas, the passivation film 70, which may be made of silicon nitride, may be formed in accordance with the following reaction equation 1.

SiH₄+N₂→SiNₓ [Reaction equation 1]

As set forth in reaction equation 1, nitrogen gas may be decomposed to form a silicon nitride film. Further, since nitrogen gas is a stable material, a larger amount of electric power may be required to form a silicon nitride film as compared to when reductive reaction gas is used to form a silicon nitride film. However, when non-reductive reaction gas such as nitrogen gas is used to form the passivation film 70, it may be possible to prevent the reduction reaction from occurring on the oxide active layer patterns 42 and 44. As a result, a haze may not occur on the thin film transistor substrate.

A process in which nitrogen gas is used as the non-reductive reaction gas to form the passivation film 70 of this exemplary embodiment has been shown and described above. However, nitrous oxide (N₂O) gas may be used as the non-reductive reaction gas. In this case, the passivation film 70 may be made of SiOx (refer to reaction equation 2 to be described below). However, the non-reductive reaction gas used in this exemplary embodiment is not limited to the above-mentioned gas and may be modified in various ways.

Subsequently, as shown in FIG. 10, a photolithography process may be performed on the passivation film 70 to form a contact hole 77 through which the drain electrode expanding portion 67 is exposed.

Finally, as shown in FIG. 11, transparent electric conductors, such as indium tin oxide (ITO) and indium zinc oxide (IZO), or reflexible electric conductors are deposited and a photolithography process is performed on the conductors to form a pixel electrode 82 connected to the drain electrode expanding portion 67.

In addition to the above-mentioned exemplary embodiment, the method of manufacturing the thin film transistor substrate according to the present invention can also be easily applied to a Color filter On Array (COA) in which a color filter is formed on a thin film transistor array.

Further, although not shown, a gate insulating film (not shown), an oxide active layer pattern (not shown), and a data wire (not shown) may be formed in accordance with modifications to be described below.

First, a gate insulating film is formed on a gate wire (not shown), and an oxide active layer is then formed thereon. Before a data wire conductive film is formed, the oxide active layer is etched to form oxide active layer patterns (not shown). The gate insulating film and the oxide active layer may be formed by a reductive sputtering method.

After that, a data wire conductive film may be formed on the oxide active layer pattern by, for example, a sputtering method, and wet or dry etching may be performed on the data wire conductive film to form data wires. Since the oxide active layer pattern and the data wire conductive film have ohmic contact characteristics, an ohmic contact layer may be omitted as described in the above-mentioned exemplary embodiment.

Then, like in the first exemplary embodiment of the present invention, a passivation film (not shown) may be formed using a non-reductive reaction gas. A pixel electrode (not shown) is also formed, thereby completing the thin film transistor substrate. Like in the above-mentioned exemplary embodiment, a passivation film may be formed at low temperature.

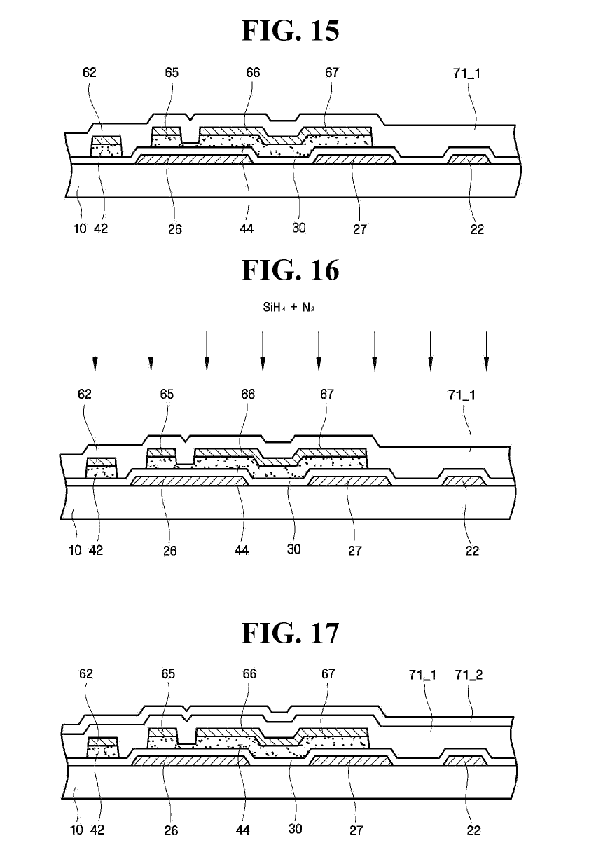

Hereinafter, a method of manufacturing a thin film transistor substrate according to a second exemplary embodiment of the present invention will be described in detail with reference to FIG. 14, FIG. 15, FIG. 16, FIG. 17, FIG. 18, and FIG. 19 and FIG. 1, FIG. 2, FIG. 3, FIG. 4, FIG. 5, FIG. 6, and FIG. 7. FIG. 14, FIG. 15, FIG. 16, FIG. 17, FIG. 18, and FIG. 19 are cross-sectional views showing a method of manufacturing a thin film transistor substrate according to a second exemplary embodiment of the present invention.

First, referring to FIG. 1, FIG. 2, FIG. 3, FIG. 4, FIG. 5, FIG. 6, and FIG. 7, gate wires 22, 26, and 27, a gate insulating film 30, oxide active layer patterns 42 and 44, and data wires 62, 65, 66, and 67 are formed on an insulation substrate 10 through the same processes as those of the first exemplary embodiment of the present invention.

Subsequently, referring to FIG. 14 and FIG. 15, a reduction barrier 71_1 may be formed on the oxide active layer patterns 42 and 44 and the data wires 62, 65, 66, and 67 using SiH₄ and N₂O gas.

The reduction barrier 71_1 of this exemplary embodiment may be formed in accordance with the following reaction equation 2.

SiH₄+N₂O→SiOx [Reaction equation 2]

As set forth in reaction equation 2, SiH₄ and N₂O gas are used as the reaction gas, which is used to form the reduction barrier 71_1 of this exemplary embodiment, unlike in the above-mentioned exemplary embodiment. For this reason, oxide, specifically, the reduction barrier 71_1 made of SiOx, is formed. That is, since the nitrogen of the nitrous oxide (N₂O) gas is stable, the nitrogen does not react with SiH₄ and an oxygen element does react with SiH₄ to form a silicon oxide film. Since N₂O gas is a non-reductive gas, oxide active layer patterns 42 and 44 may not be reduced during the formation of the reduction barrier 71_1. As a result, a haze may not occur on the thin film transistor substrate.

Like the passivation film (see 70 in FIG. 9) of the previous exemplary embodiment, a reduction barrier 71_1 of this exemplary embodiment may be formed by a low temperature reactive chemical vapor deposition method. In this case, the deposition temperature may be, for example, 200° C. or less, and preferably, 150° C. or less to prevent the reduction of the oxide active layer patterns 42 and 44. The combination of a low temperature method such as a low temperature reactive chemical vapor deposition method and a deposition method using SiH₄ and N₂O gas may be used to form the reduction barrier 71_1.

Subsequently, referring to FIG. 16 and FIG. 17, a passivation film 71_2 is formed on the reduction barrier 71_1. SiH₄ and nitrogen gas may be used as the reaction gas to form the passivation film 71_2 of this exemplary embodiment. Since the reduction barrier 71_1 has been formed, the reduction of the oxide active layer patterns 42 and 44 may be prevented. Accordingly, the passivation film 71_2 of this exemplary embodiment may further include SiH₄, nitrogen gas, and ammonia gas, which may be used as the reductive reaction gas. In this case, the passivation film 71_2 made of SiNₓ may be formed in accordance with the following reaction equation 3.

SiH₄+N₂+NH₃→SiNₓ [Reaction equation 3]

In reaction equation 3, the nitrogen gas controls the reaction rate, but is not involved in the reaction. Nitrogen elements contained in the ammonia gas and silicon elements contained in SiH₄ bond with each other to form a silicon nitride film. In this case, the reduction reaction of the oxide active layer patterns 42 and 44, which is caused by ammonia gas or H radicals generated during the decomposition of ammonia, may be prevented by the above-mentioned reduction barrier 71_1.

Reductive chemical vapor deposition may be performed at a low temperature, for example, 200° C. or less, and preferably, 150° C. or less, which may efficiently protect the insulation substrate 10 and the oxide active layer patterns 42 and 44 during the formation of the passivation film 71_2 of this exemplary embodiment.

The reduction barrier 71_1 and the passivation film 71_2 may be formed by an in-situ process in one chamber. That is, the reduction barrier 71_1 may be formed on the insulation substrate 10, and the reaction gas used to form the reduction barrier 71_1 is then discharged from a chamber. Subsequently, the reaction gas used to form the passivation film 71_2 may be injected into the chamber to form the passivation film 71_2. As a result, the processing time may not be increased significantly.

After that, as shown in FIG. 18, a contact hole 77 may be formed in the reduction barrier 71_1 and the passivation film 71_2 to expose the drain electrode expanding portion 67.

Finally, as shown in FIG. 19, a pixel electrode 82, which may be made of ITO, is formed on the passivation film 71_2.

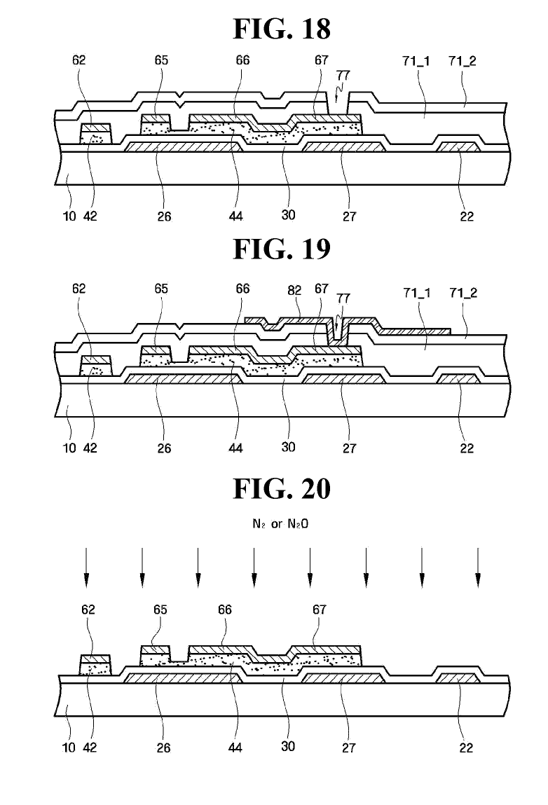

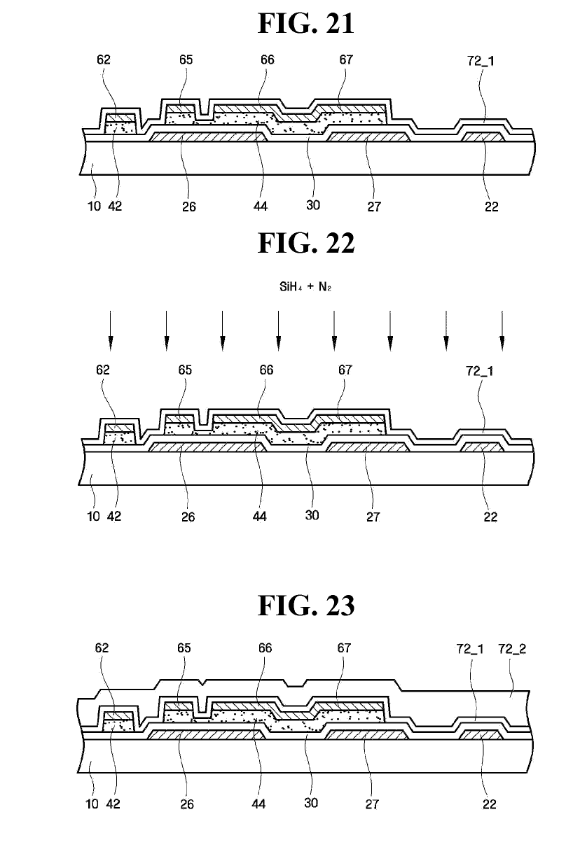

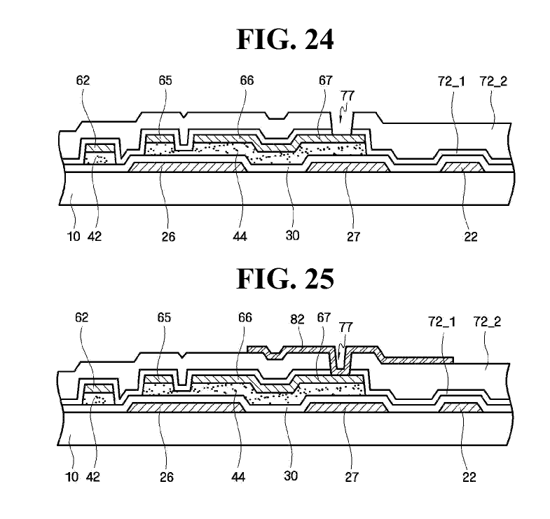

Hereinafter, a method of manufacturing a thin film transistor substrate according to a third exemplary embodiment of the present invention will be described in detail with reference to FIG. 20, FIG. 21, FIG. 22, FIG. 23, FIG. 24, and FIG. 25 and FIG. 1, FIG. 2, FIG. 3, FIG. 4, FIG. 5, FIG. 6, and FIG. 7. FIG. 20, FIG. 21, FIG. 22, FIG. 23, FIG. 24, and FIG. 25 are cross-sectional views showing a method of manufacturing a thin film transistor substrate according to a third exemplary embodiment of the present invention.

First, referring to FIG. 1, FIG. 2, FIG. 3, FIG. 4, FIG. 5, FIG. 6, and FIG. 7, gate wires 22, 26, and 27, a gate insulating film 30, oxide active layer patterns 42 and 44, and data wires 62, 65, 66, and 67 are formed on an insulation substrate 10 through the same processes as those of the first exemplary embodiment of the present invention.

Subsequently, referring to FIG. 20 and FIG. 21, the oxide active layer patterns 42 and 44 and the data wires 62, 65, 66, and 67 may be exposed to plasma. A non-reductive reaction gas may be used to expose the patterns and wires to plasma. The non-reductive reaction gas does not include hydrogen elements. Specifically, N₂ or N₂O gas may be used as the non-reductive reaction gas. When the oxide active layer patterns 42 and 44 and the data wires 62, 65, 66, and 67 are exposed to plasma as described above by nitrogen elements used as non-reductive elements, a thin nitride film 72_1 may be formed on the oxide active layer patterns 42 and 44 and the data wires 62, 65, 66, and 67. When the nitride film 72_1 is formed, it may be possible to prevent the reduction of the oxide active layer patterns 42 and 44 when a passivation film 72_2 is formed. The nitride film 72_1 may have a thickness in the range of, for example, 0.1 to 9.9 nm, but the thickness of the nitride film 72_1 is not limited to this range.

The nitride film 72_1 may be formed by exposing the oxide active layer patterns 42 and 44 and the data wires 62, 65, 66, and 67 to low temperature plasma in order to prevent the deterioration of the oxide active layer patterns 42 and 44 and the insulation substrate 10. In this case, during the exposure to low temperature plasma, the temperature of the plasma may be, for example, 200° C. or less, and preferably, 150° C. or less. N₂ or N₂O gas may be used as the plasma reaction gas.

Subsequently, referring to FIG. 22 and FIG. 23, the passivation film 72_2 may be formed on the nitride film 72_1. SiH₄ and nitrogen gas may be used as the reaction gas to form the passivation film 72_2 of this exemplary embodiment. When the nitride film 72_1 has been formed, the reduction of the oxide active layer patterns 42 and 44 may be prevented. Accordingly, the passivation film 72_2 of this exemplary embodiment may further include SiH₄, nitrogen gas, and ammonia gas, which may be used as reductive reaction gas. In this case, the passivation film 72_2, which may be made of SiNₓ, may be formed as set forth in reaction equation 3 of the previous exemplary embodiment.

Reductive chemical vapor deposition may be performed at a low temperature, for example, 200° C. or less, and preferably, 150° C. or less, which may efficiently protect the insulation substrate 10 and the oxide active layer patterns 42 and 44 during the formation of the passivation film 72_2 of this exemplary embodiment.

The exposure to low temperature plasma and the formation of the passivation film 72_2 may be performed by an in-situ process in one chamber, like in the second exemplary embodiment of the present invention. Accordingly, the processing time may not be increased significantly.

Finally, referring to FIG. 24 and FIG. 25, a contact hole 77 may be formed in the nitride film 72_1 and the passivation film 72_2 to expose the drain electrode expanding portion 67. A pixel electrode 82 may also be formed, thereby completing a thin film transistor substrate.

As described above, it may be possible to obtain one or more of the following effects by manufacturing a thin film transistor substrate according to the exemplary embodiments and modifications of the present invention.

First, a passivation film may be formed using a non-reductive reaction gas, plasma exposure may be performed before the formation of a passivation film, and a reduction barrier may be made of silicon oxide. Accordingly, it may be possible to prevent the reduction of oxide active layer patterns. As a result, it may also be possible to prevent a haze from occurring on a thin film transistor substrate.

Second, since a passivation film may be deposited using a low temperature chemical vapor deposition method or a low temperature reactive sputtering method, it may be possible to prevent the reduction of oxide active layer patterns.

Third, since a process of forming a passivation film may be performed at a low temperature, it may be possible to use an insulation substrate made of inexpensive soda lime glass. As a result, it may be possible to reduce manufacturing cost of a thin film transistor substrate.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method for manufacturing a thin film transistor substrate, the method comprising:
forming gate wires on an insulation substrate;
forming oxide active layer patterns on the gate wires;
forming data wires on the oxide active layer patterns, the data wires crossing the gate wires;
forming a passivation film on the oxide active layer patterns and the data wires using a non-reductive reaction gas and SiH₄; and
forming pixel electrodes on the passivation film.

2. The method of claim 1, wherein forming the passivation film comprises forming SiNₓ using nitrogen (N₂) gas as the non-reductive reaction gas.

3. The method of claim 1, wherein forming the passivation film comprises forming SiOx using nitrous oxide (N₂O) as the non-reductive reaction gas.

4. The method of claim 2, wherein forming the passivation film is performed by chemical vapor deposition at a temperature of 200° C. or less.

5. The method of claim 4, wherein the temperature is 150° C. or less.

6. The method of claim 3, wherein forming the passivation film is performed by chemical vapor deposition at a temperature of 200° C. or less.

7. The method of claim 6, wherein the temperature is 150° C. or less.

8. The method of claim 2, wherein, a flux ratio of SiH₄ to the non-reductive reaction gas is 1:10 to 1:100.

9. The method of claim 3, wherein a flux ratio of SiH₄ to the non-reductive reaction gas is 1:10 to 1:100.

10. The method of claim 1, wherein the oxide active layer pattern comprises InZnO, GaInZnO, or ZnO.

11. A method for manufacturing a thin film transistor substrate, the method comprising:
forming gate wires on an insulation substrate;
forming oxide active layer patterns on the gate wires;
forming data wires on the oxide active layer patterns, the data wires crossing the gate wires;
forming a passivation film by depositing a thin film made of SiNₓ on a thin film made of SiOx after depositing the thin film made of SiOx on the oxide active layer patterns and the data wires using nitrous oxide (N₂O) gas and SiH₄; and
forming pixel electrodes on the passivation film.

12. The method of claim 11, wherein depositing the thin film made of SiOx and depositing the thin film made of SiNₓ are performed by an in-situ process.

13. The method of claim 11, wherein forming the passivation film is performed by chemical vapor deposition at a temperature of 200° C. or less.

14. The method of claim 13, wherein the temperature is 150° C. or less.

15. The method of claim 11, wherein a flux ratio of SiH₄ to nitrous oxide (N₂O) gas is 1:10 to 1:100.

16. The method of claim 11, wherein the oxide active layer pattern comprises InZnO, GaInZnO, or ZnO.

17. A method for manufacturing a thin film transistor substrate, the method comprising:
forming gate wires on an insulation substrate;
forming oxide active layer patterns on the gate wires;
forming data wires on the oxide active layer patterns, the data wires crossing the gate wires;
exposing the oxide active layer patterns to plasma using a non-reductive reaction gas;
forming a passivation film on the oxide active layer patterns and the data wires; and
forming pixel electrodes on the passivation film.

18. The method of claim 17, wherein the non-reductive reaction gas is nitrogen (N₂) gas or nitrous oxide (N₂O) gas.

19. The method of claim 17, wherein the passivation film is formed by an in-situ process after the oxide active layer patterns are exposed to plasma.

20. The method of claim 17, wherein the oxide active layer patterns are exposed to plasma at a temperature of 200° C. or less.

21. The method of claim 17, wherein the oxide active layer comprises InZnO, GaInZnO, or ZnO.

22. A method for manufacturing a thin film transistor substrate, the method comprising:
forming gate wires on an insulation substrate;
forming oxide active layer patterns on the gate wires;
forming data wires on the oxide active layer patterns, the data wires crossing the gate wires;
forming a passivation film on the oxide active layer patterns and the data wires; and
forming pixel electrodes on the passivation film,
wherein the forming of the passivation film is performed by chemical vapor deposition at a temperature of 200° C. or less.

23. The method of claim 22, wherein the temperature is 150° C. or less.

24. The method of claim 22, wherein forming the passivation film is performed using a non-reductive reaction gas and SiH₄.
